(19) United States
(12) Patent Application Publication
(10) Pub. No.: US 2006/0012408 A1
(43) Pub. Date: Jan. 19, 2006

(54) Differential clock input buffer

(75) Inventor: Lawrence J. Kushner, Andover, MA (US)

Correspondence Address: HAMILTON, BROOK, SMITH & REYNOLDS, P.C., 530 VIRGINIA ROAD, P.O. BOX 9133, CONCORD, MA, 01742-9133, US

(73) Assignee: Kenet, Inc., Reading, MA (US)

(21) Appl. No.: 11/175,976

(22) Filed: Jul. 6, 2005

Related U.S. Application Data
(60) Provisional application No. 60/585,682, filed on Jul. 6, 2004.

(51) Int. Cl. H03B 1/00

(52) U.S. Cl. 327/112

(57) ABSTRACT

A compact, differential clock input buffer that converts single-end or differential sine wave or square wave inputs into complementary squarewave digital outputs, with low-jitter, and 50% duty cycle outputs. Low-noise oscillator design concepts are applied to provide at least two stages of regeneration. This minimizes the time the clock buffer spends in the noise-susceptible linear region. A first stage latching circuit consists of a pair of cross coupled transistors (i.e., a differential transistor pair) with resistive loads to provide gain, limiting, hysteresis, and latching functions. These transistors operate in a linear region for only a very small range of input voltage. A second stage latching circuit, which can use a current mirror, is also provided as a pair of cross coupled transistors with resistive loads. The second stage latch provides positive feedback to further limit the linear operating range.

### RELATED APPLICATION(S)

This application claims the benefit of U.S. Provisional Application No. 60/585,682, filed on Jul. 6, 2004. The entire teachings of the above application(s) are incorporated herein by reference.

### BACKGROUND OF THE INVENTION

The present invention relates to circuits for generating digital clock signals. Many different circuits require a generation of a digital clock signal having a nearly 50% duty cycle with sharp rise and fall times. Such clock signals are typically generated using a crystal oscillator and level shifting buffer circuits that convert the crystal oscillator output to a signal having the voltage and current levels expected by logic circuits.

Once such circuit is described in a paper by Riley, et al. entitled “Techniques for In-Band Phase Noise Reduction in ΔΣSynthesizers”, IEEE Transactions on Circuits and Systems—II, Analog and Digital Signal Processing, Vol. 50, No. 11, November 2003, at pages 800-802. In that circuit, a self-biasing crystal oscillator provides a sinusoidal output signal via a single ended, subthreshold output drive transistor pair. The output signal is a sinusoid with an amplitude of approximately eight hundred millivolts (mV) peak to peak.

A Complimentary Metal Oxide Semiconductor (CMOS) level shifter then converts this sinusoid to a digital signal having full CMOS swing logic levels of approximately 3 volts. The level shifter has a first stage similar to a low noise amplifier (LNA) and a second stage that acts as a latch.

The first stage of the level shifter is provided by an Alternating Current (AC) bipolar, differential transistor pair. The first stage may use resistive loads; Direct Current (DC) bias levels are provided by a pair of diodes connected between the input stages and a voltage reference.

The second stage use cross coupled transistors and resistive load transistors to mirror a push-pull CMOS output stage, to generate complimentary outputs with the required voltage swing.

There are several shortcomings with the clock circuit design described in the Riley article. For one, the use of a simple linear differential amplifier as a first stage, although designed as a low noise amplifier, will actually add noise to the resulting output. This is due to the fact that it operates largely in the linear region.

In addition, the single latch stage provided by the second stage will still exhibit some level of jitter.

### SUMMARY OF THE INVENTION

The present invention is a differential clock input buffer circuit that converts single and/or differential input signals into a pair of complimentary, square wave digital outputs. The input signal(s) may have a sine wave, square wave or other shape; indeed the operation of the circuit is relatively independent of the exact input wave form shape, its amplitude, or even its common mode voltage.

The circuit can be used to produce a nearly 50% duty cycle complimentary digital output. It exhibits improved noise immunity and less jitter as compared to previous clock circuit designs.

In brief summary, the invention uses a two stage approach to level shifting, adapting concepts of low-noise oscillator design to provide two stages of regeneration in a clock buffer circuit. In particular, a first stage latching circuit consists of a pair of cross coupled bi-stable transistors with resistive loads to provide gain, limiting, hysteresis, and latching functions. The transistors in the first stage are designed to be of a relatively small size in the available circuit technology, to provide as fast as possible switching performance.

These transistors operate in a linear region, as controlled by the cross-coupled latch arrangement which creates positive feedback, to restrict operation to a small range of input voltages. A voltage to current converter may be used to drive the first stage.

A second stage latching circuit, which may use circuits adapted to mirror currents in the first stage, is also provided as a pair of cross coupled transistors with resistive loads. The second stage latch provides further gain, limiting, hysteresis, and latching, and is preferably biased at the center of an output buffer's range, to provide better duty cycle control over a wider range of signal levels.

The circuit provides improved input hysteresis for greater noise immunity, and limits jitter production by ensuring that the edges of the resulting clock signals are as fast as possible, while minimizing the time that the clock buffer spends in the linear region.

### BRIEF DESCRIPTION OF THE DRAWINGS

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIG. 1 is a schematic diagram of one preferred implementation of a input clock buffer according to the present invention.

FIG. 2 illustrates the voltage input (Vᵢₙ) versus voltage output (Vₒᵤₜ) for the first stage latch circuit.

FIG. 3 shows a similar diagram for the second stage latch circuit.

FIGS. 4 and 5 illustrate the duty cycle output as a function of single and balanced input drive levels.

FIGS. 6, 7, and 8 illustrate the response to a triangle wave input at various places within the clock buffer circuit.

FIG. 9 is a plot of input voltage versus output voltage at various places.

### DETAILED DESCRIPTION OF THE INVENTION

A description of preferred embodiments of the invention follows.

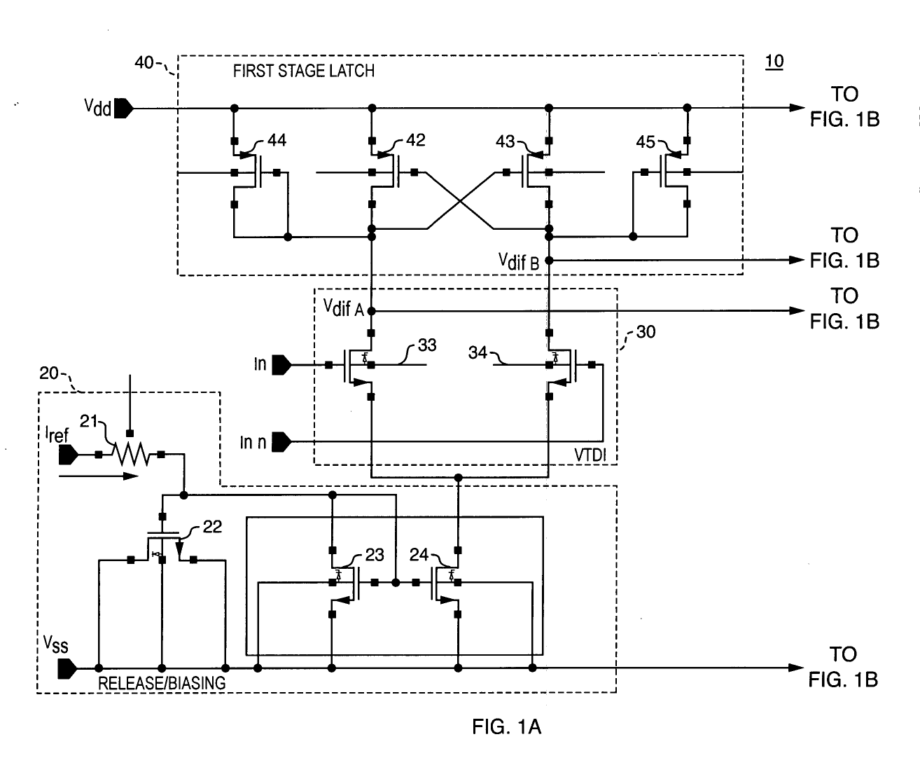

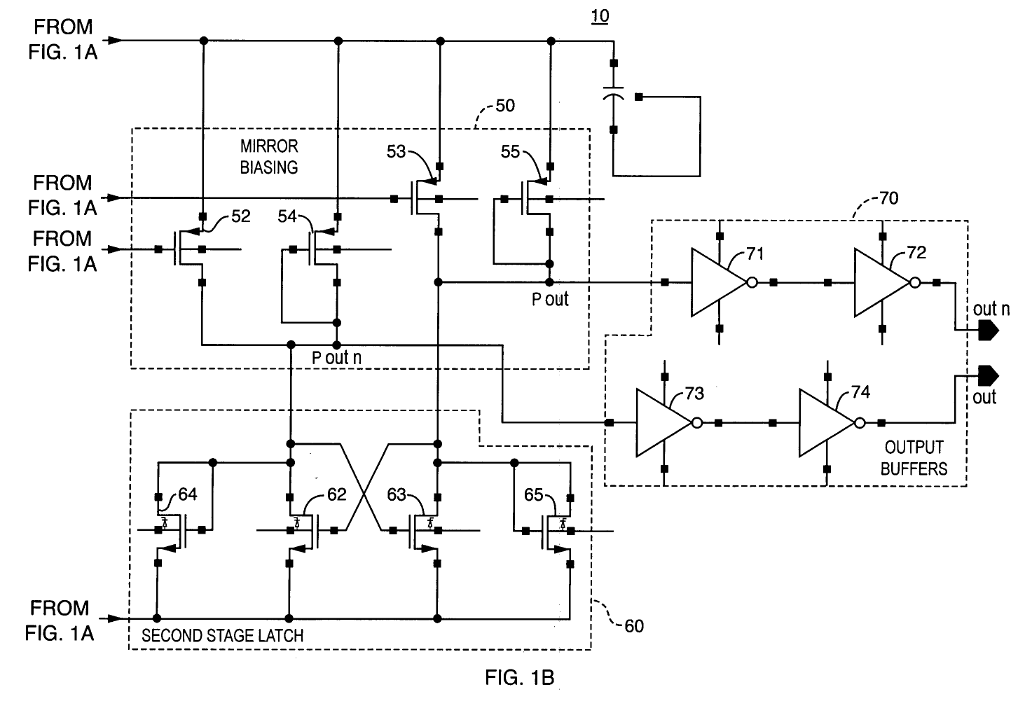

FIG. 1 is a schematic diagram of one preferred embodiment of a clock buffer circuit 10 according to the present invention. The circuit 10 consists of several functions, including a reference/biasing circuit 20, a voltage to current (V-to-I) converter (differential pair) 30, a first stage latch 40, a mirror/biasing circuit 50, a second stage latch 60, and output buffers 70.

The input signal(s) may be single or double ended. If a single ended signal, it is provided at terminal IN (or just at INN, with the other input terminal biased somewhere near vdd/2); if double ended, they are provided to inputs IN and IN_{N}. The voltage to current converter 30 converts these input voltage(s) to differential currents at nodes Vdiff_{A} and Vdiff_{B}. The voltage to current converter 30 consists of a pair of CMOS transistors 33, 34 arranged as a differential amplifier, to provide current from a source Vss (and to reject common-mode signals and noise).

A reference/biasing circuit 20 provides a reference current to differential transistor pair 33, 34. The reference/biasing circuit may consist of adjustable resistive load 21 and multiple drive transistors 22, 23, 24. Circuit 20 could also be implemented as cascade current source/mirror for somewhat improved performance.

First stage latch 40 consists of a pair of bi-stable, cross coupled transistors 42, 43. Nodes Vdiff_{A} and Vdiff_{B} provide source terminal inputs to transistors 42, 43, respectively. Transistors 42, 43 are diode-connected field effect transistors (FETs) by resistive load transistors 44, 45. The ratio of the gate widths for each FET with respect to its respective load (i.e., the ratio of the gate width for transistor 44 to that of transistor 42 and of transistor 45 to that of transistor 43) are selected to control the desired switching and hysteresis characteristics. Also, the ratio of the input differential pair 42, 43 gate width to the load transistor 44, 45 gate width determines the first stage linear gain (i.e., the ratio of the input transconductance to load transconductance.) If speed of operation is important, the transistors 42, 43 used in the first stage latch 40 are selected to be of a relatively small size. For example, they may have a gate width of only six microns or less. By providing the first stage 40 with transistors 42, 43 that are as small as possible, they will switch between the two bi-stable states as fast as fast as possible. The size selected for these transistors 42,43 does involve a tradeoff, however, between the desired amount of balanced drive current versus the desired hysteresis.

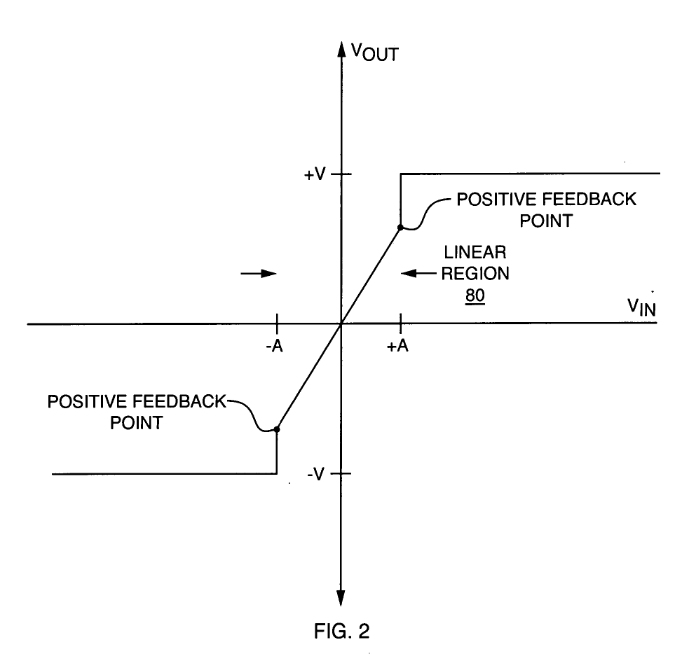

Turning attention briefly to FIG. 2, there is shown a diagram of desired input voltage Vᵢₙ versus output voltage Vₒᵤₜ for the first stage latch. A linear operating region 80 extends over only a very short range due to the positive feedback of the cross-coupled transistors. Thus, once the input voltage rises above A+volts in a positive direction or below −A volts in a negative direction, positive feedback in the latching circuit takes effect, transistors 42, 43 no longer operate in the linear region, and the output voltage swings to levels +V or −V, respectively. Thus maximum hysteresis is provided so that the output switches to the desired level A or −A as soon as possible.

Nodes Vdiff_{A} and Vdiff_{B} are also coupled to drive respective inputs of the mirroring circuit 50. Mirroring circuit itself consists of transistors 52, 53 and respective resistive loads 54, 55. The mirroring transistors 52, 53 are set to be the same size as the transistors 42, 43 in the first stage. These transitors 52, 53 serve to mirror currents in the first stage at at nodes Pout and Pout_{N}.

Nodes Pout and PoutN are used as nodes for the second stage. Transistors 54, 55 are arranged to set the bias at nodes Pout and Pout_{N} so as to be centered at approximately the threshold of output buffers 70. This provides for better control over duty cycle over a wide range of input levels.

The second stage latch 60 is similar in configuration to the first stage latch 30. It is again provided by a pair of bi-stable, cross coupled differential pair transistors 62, 63 and their respective resistive loads provided by transistors 64, 65. The loads in the second stage are referenced to Vss. As with the first stage, ratio of the gate widths of the differential pair 62, 63 versus the loads 64, 65 are chosen to control hysteresis and gain. The second stage latch 60 is designed to provide an even sharper response over an even smaller variation of input voltage due to its gain, limiting, and hysteresis.

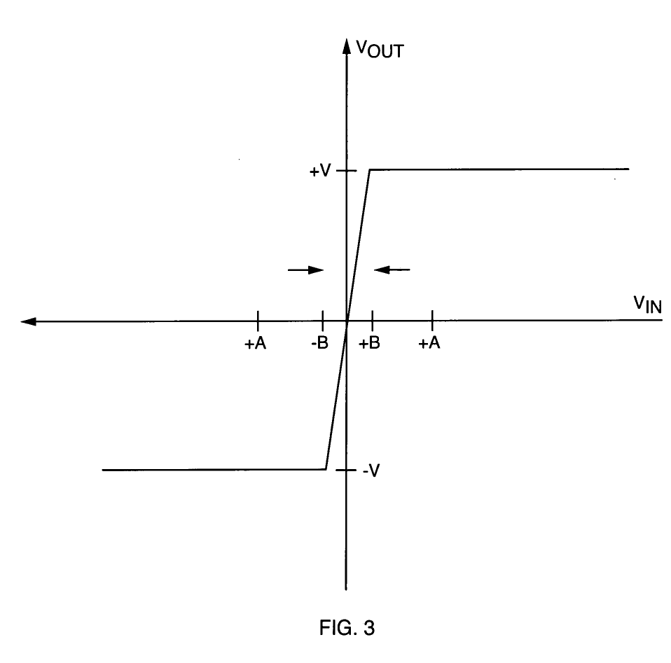

FIG. 3 shows a diagram of Vᵢₙ versus Vₒᵤₜ for the second stage 60. It is evident that the linear region 80 is now extended over even shorter range from −B to +B, a much shorter than the range −A to +A exhibited by the first stage 40 alone.

Nodes Pout and Pout_{N} are also coupled to buffers 70. Buffers 70, in the illustrated embodiment are provided by inverters 71, 72, 73, 74. Series connected inverters 71, 72 are coupled to the Pout node to produce output signal Out_{N}; and series connected inverters 73, 74 operate on the Pout_{N} node to provide output signal Out. The inverters 70 are implemented in the desired Complimentary Metal Oxide Semiconductor (CMOS) technology.

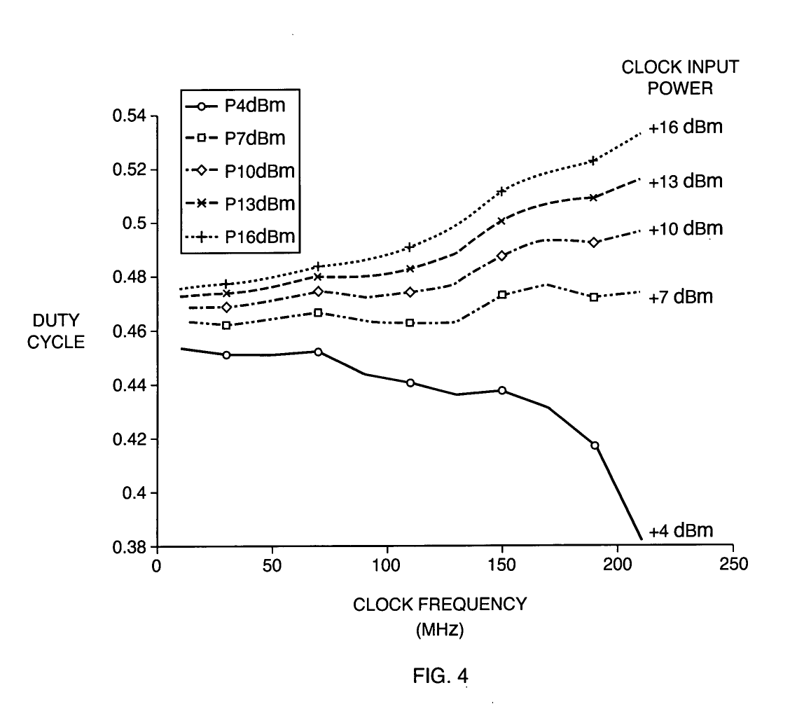

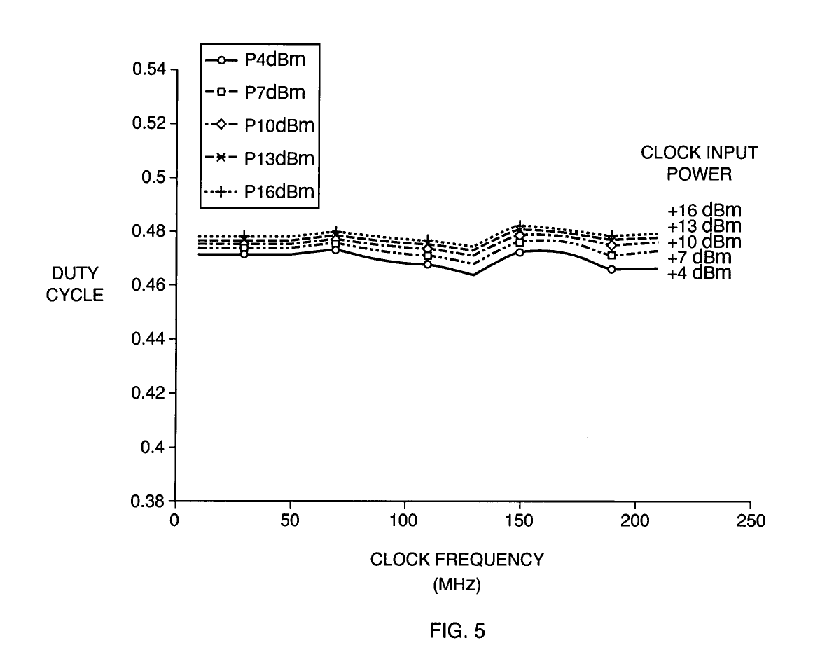

FIGS. 4 and 5 illustrate a duty cycle out as a function of single ended and balanced drive level inputs. Duty cycles are maintained over a range from 42% up to 52% for operating frequencies ranging from 0 up to approximately 200 MegaHertz (MHz). The operation for balanced drive is even far more predictable, exhibiting between 47% and 48% duty cycle over a very large range of operating clock frequencies and input power levels from 4 to 16 decibels/millivolt (dBm).

It is understood now that clock input buffer 10 can be used to convert single ended or differential sign wave or square wave inputs to complimentary square wave digital outputs with low jitter and nearly 50% duty cycle. These outputs are maintained over a wide range of input power levels, exhibiting very little change in duty cycle.

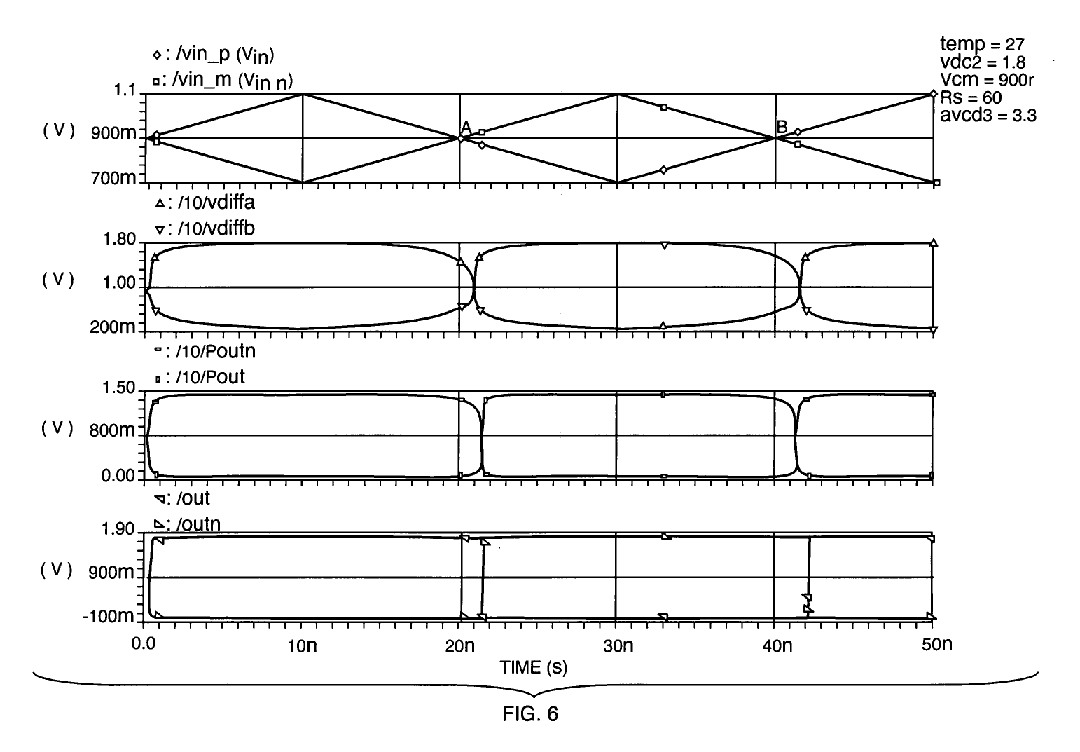

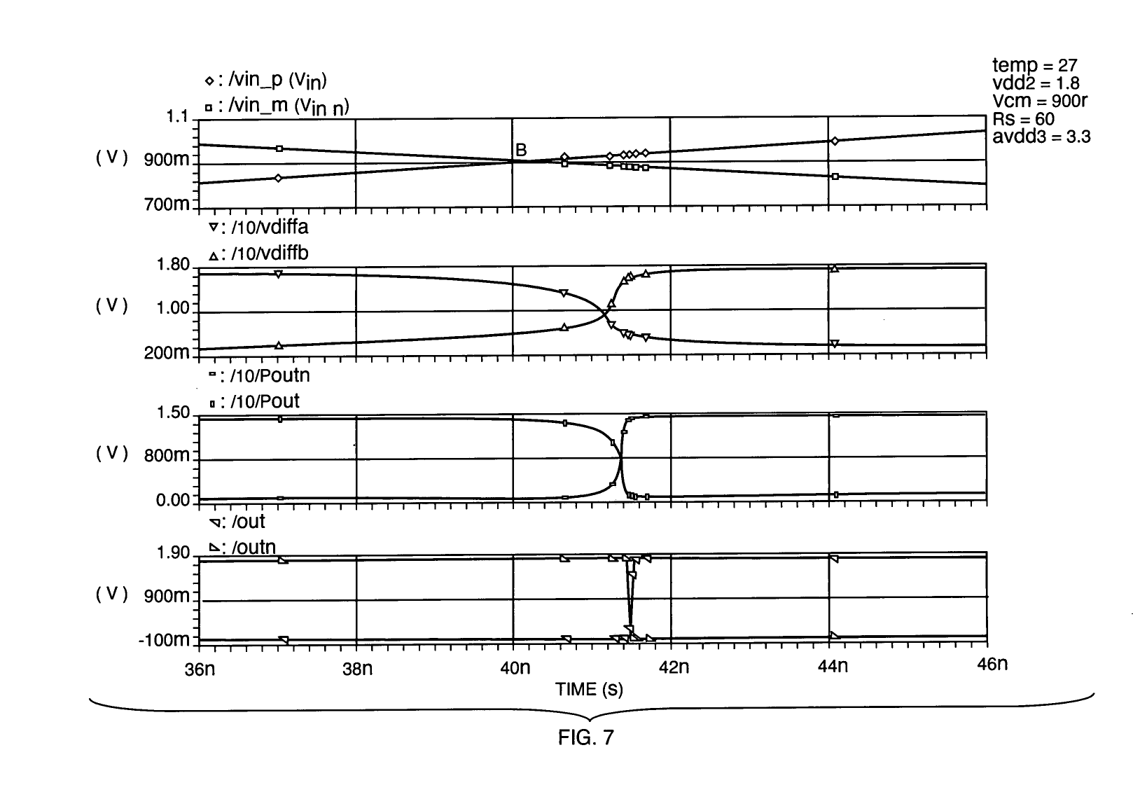

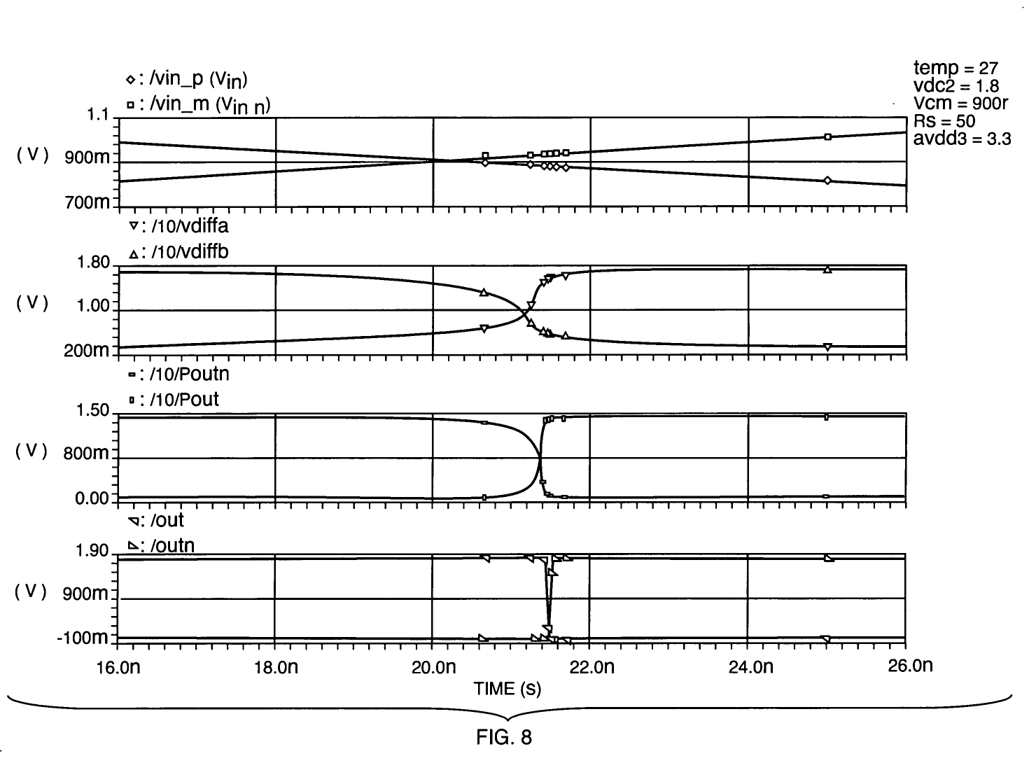

FIG. 6 illustrates a simulated transient response of the clock buffer 10, over a time period ranging from 0 to 50 nanoseconds (ns). FIGS. 7 and 8 are similar, but are zoomed in on the time axis, and range from 36 ns to 46 ns, and from 16 ns to 26 ns, respectively.

The top trace in these figures shows an input triangle waveform for the “plus” and “minus” inputs, Vᵢₙ and V_{inn.} ranging from 700 millivolts (mv) to 1.1 volt (v).

The second trace illustrates a typical output of the first stage 40 latch, at nodes Vdiff_{A} and Vdiff_{B}. Note the effect of hysteresis is to delay the crossover point “A”; but the change in response amplitude is now much more rapid.

The third trace in FIGS. 6, 7, and 8 illustrates the output of the second stage 60 nodes Pout and Pout_{N}; it is much sharper now. The bottom traces in each of these figures show the output provided by CMOS buffers 70.

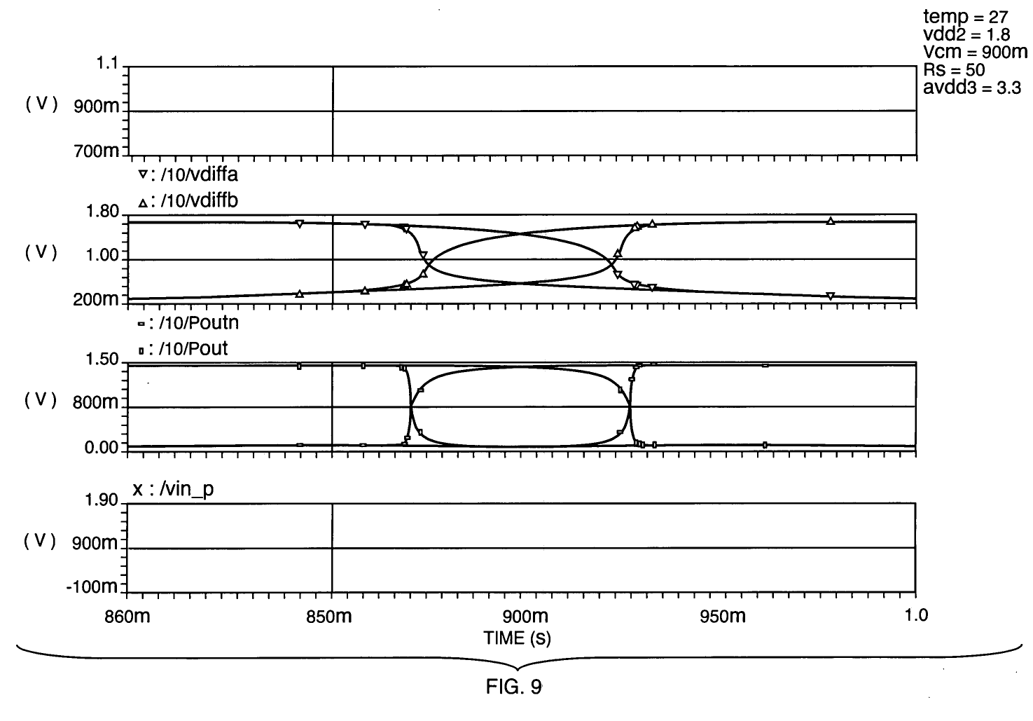

The plots of FIG. 9 illustrate input voltage versus output at the same nodes (input; Vdiff_{A} and Vdiff_{B}; Pout and PoutN; and the CMOS buffers). The hysteresis effect is clearly evident from these plots as well.

While this invention has been particularly shown and described with references to preferred embodiments thereof, it will be understood by those skilled in the art that various changes in form and details may be made therein without departing from the scope of the invention encompassed by the appended claims.

What is claimed is:

1. A clock buffer circuit for providing a complimentary pair of square wave output signals from an input signal comprising:
a first stage differential latch, connected to receive the input signal, and to provide complimentary output signals at a pair of differential latch signal nodes Vdiff_{A} and Vdiff_{B};
current mirrors, coupled to the differential latch signal nodes, to provide mirrored differential signals at mirror nodes Pout and Pout_{N}; and
a second stage differential latch, coupled to mirror nodes Pout and Pout_{N}, to increase the gain, limiting, and hysteresis of the signals and to provide the complimentary pair of square wave output signals.

2. A circuit as in claim 1 additionally comprising:
an input biasing circuit, coupled to the first stage differential latch.

3. A circuit as in claim 2 wherein the input biasing circuit provides approximately equal drive current to nodes Vdiff_{A} and Vdiff_{B}.

4. A circuit as in claim 2 wherein the input signal is provided as a single ended input signal.

5. A circuit as in claim 2 wherein the input signal is provided as a pair of balanced signals.

6. A circuit as in claim 1 wherein the first stage differential latch further comprises a pair of cross coupled transistors having relatively small geometry.

7. A circuit as in claim 6 wherein a gate width of the transistors in the first stage latch is approximately 6 microns.

8. A circuit as in claim 1 wherein the transistors in the first stage latch operate in linear mode over a limited range of input voltages.

9. A circuit as in claim 1 additionally comprising:
complimentary output buffer circuits, coupled to the complimentary pair of square wave output signals.
